(19) United States
(12) Patent Application Publication
(10) Pub. No.: US 2025/0006737 A1
(43) Pub. Date: Jan. 2, 2025

(54) STACKED CMOS TRANSISTOR STRUCTURES WITH COMPLEMENTARY CHANNEL MATERIALS

(71) Applicant: Intel Corporation, Santa Clara, CA (US)

(72) Inventors: Aryan Navabi-Shirazi, Portland, OR (US); Michael Babb, Portland, OR (US); Kai Loon Cheong, Hillsboro, OR (US); Cheng-Ying Huang, Hillsboro, OR (US); Mohammad Hasan, Portland, OR (US); Leonard P. Guler, Hillsboro, OR (US); Marko Radosavljevic, Portland, OR (US)

(73) Assignee: Intel Corporation, Santa Clara, CA (US)

(21) Appl. No.: 18/216,520

(22) Filed: Jun. 29, 2023

(51) Int. Cl. H01L 27/092; H01L 21/822; H01L 21/8238; H01L 29/06; H01L 29/423; H01L 29/66; H01L 29/775; H01L 29/786

(52) U.S. Cl. CPC H01L 27/0922; H01L 21/8221; H01L 21/823807; H01L 21/823814; H01L 29/0673; H01L 29/42392; H01L 29/66439; H01L 29/775; H01L 29/78696

(57) ABSTRACT

A material stack comprising a plurality of bi-layers, each bi-layer comprising two semiconductor material layers, is fabricated into a transistor structure including a first stack of channel materials that is coupled to an n-type source and drain and in a vertical stack with a second stack of channel materials that is coupled to a p-type source drain. Within the first stack of channel material layers a first of two semiconductor material layers may be replaced with a first gate stack while within the second stack of channel materials a second of two semiconductor material layers may be replaced with a second gate stack.

### BACKGROUND

For integrated circuits (ICs) employing complementary metal oxide semiconductor (CMOS) technology, transistors of different polarities can be made of a single semiconductor material, such as silicon. However, transistors of different polarities can advantageously employ different semiconductor materials. For example, in one IC die area there may be n-type transistors that have Si channel material offering high electron mobility while in another area of the IC die there may be p-type transistors that have SiGe alloy channel material offering high hole mobility.

Advanced CMOS ICs may utilize a stacked transistor structure comprising a vertical stack of a plurality of nanoribbon or wire (RoW) channels, which promise greater device densities. Some stacked transistor implementations may again include n-type transistors with Si channel material in a region of an IC die. Other stacked transistor implementations may include p-type stacked transistors with SiGe alloy channel material in a region of an IC die. However, the channel material within a given stacked transistor structure is typically the same, for example either Si or SiGe. Such a limitation inhibits the performance of either a PMOS transistor implemented in the stack (if Si) or an NMOS transistor implemented in the stack (if SiGe) since a stack of one semiconductor material does not offer both highest hole mobility and highest electron mobility.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is an isometric illustration of a stacked CMOS transistor structure comprising complementary channel materials, in accordance with some embodiments;

FIG. 2 is a flow diagram illustrating methods for forming a stacked CMOS transistor structure comprising complementary channel materials, in accordance with some embodiments;

FIG. 3 is a flow diagram illustrating methods for forming complementary channel materials for a stacked CMOS transistor structure, in accordance with some embodiments;

FIGS. 4A, 4B, 4C, 4D, and 4E illustrate cross-sectional views through a first plane of a stacked material layer structure evolving to include complementary channel materials coupled to complementary source and drain materials, in accordance with some embodiments of the methods illustrated in FIG. 3;

FIGS. 5A, 5B, 5C, 5D and 5E illustrate cross-sectional views through a first plane of a stacked material layer structure evolving to include complementary channel materials coupled to complementary source and drain materials, in accordance with some alternative embodiments of the methods illustrated in FIG. 3;

FIGS. 6A, 6B, 6C, 6D, 6E and 6F illustrate cross-sectional views through a second plane of the stacked material structures illustrated in FIG. 4E or 5E further evolving to include complementary channel materials coupled to complementary gate stack materials, in accordance with some embodiments of the methods illustrated in FIG. 2;

FIG. 7 illustrates a cross-sectional view through the first plane of the stacked CMOS transistor structure illustrated in FIG. 6F, in accordance with some embodiments;

FIG. 8 illustrates a mobile computing platform and a data server machine employing an IC device with stacked CMOS transistor structures that include complementary channel materials, in accordance with some embodiments; and

FIG. 9 is a functional block diagram of an electronic computing device, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

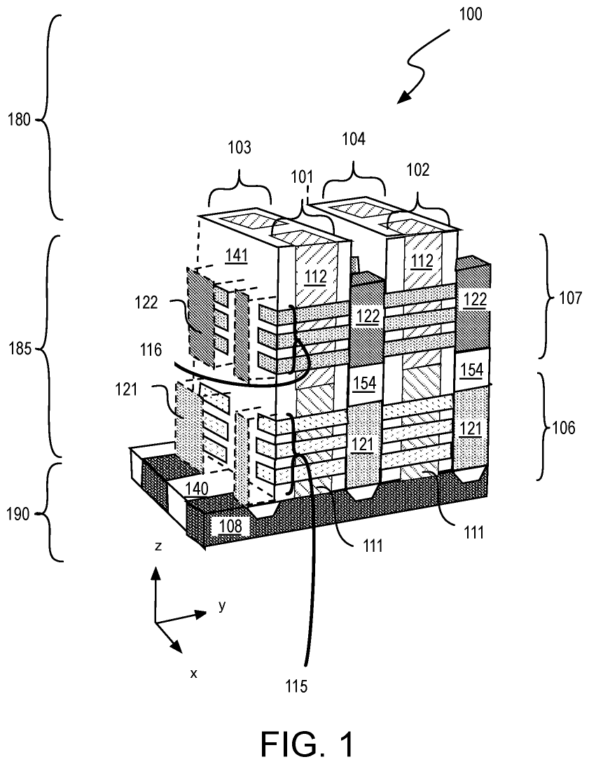

FIG. 1 is an isometric illustration of an integrated circuit (IC) portion 100 comprising a plurality of stacked CMOS transistor structures 101, 102, 103 and 104. Although four stacked CMOS transistor structures are illustrated, any number of such stacked CMOS transistor structures may be arrayed over an area or footprint of an IC die. Each stacked CMOS transistor structure (e.g., 101) is a (nano) ribbon or wire (RoW) transistor structure that includes a stack of an integer number m first channel material layers 115 within vertical stack that further includes a stack of another integer number n second channel material layers 116. In FIG. 1, integer numbers m and n are equal (e.g., three), but they may differ and may each be any non-zero number (e.g., 1-9). CMOS transistor structures 101-104 are within a device layer 185 that is under frontside layers 180, which may include one or more metallization levels (not depicted) interconnecting terminals of transistor structures 101-104 with other circuit nodes to form any suitable IC topology. Device layer 185 is over backside layers 190, which may comprise any suitable support substrate material 108 and/or device isolation material 140 and/or one or more other metallization levels (not depicted) that may further interconnect terminals of transistor structures 101-104 with other circuit nodes of an IC.

Channel material layers 115 and 116 comprises complementary channel materials. The channel materials are referred to herein as “complementary” because one channel material is advantageous for an NMOS portion of CMOS transistor structure 101 while the other channel material is advantageous for a PMOS portion of CMOS transistor structure 101. In exemplary embodiments, channel material within an NMOS portion of CMOS transistor structure 101 offers higher electron mobility than the channel material within the PMOS portion of CMOS structure 101. Channel material within the PMOS portion of CMOS transistor structure 101 likewise offers higher hole mobility than the channel material within the NMOS portion of CMOS transistor structure 101. The high complementary carrier mobilities may therefore enable high drive currents independently for both the NMOS and PMOS portions of CMOS transistor structure 101. Although NMOS and PMOS portions of CMOS transistor structure 101 may be vertically stacked with either NMOS or PMOS portions above or below the other, for clarity of discussion, channel material layers 115 are referred to as being within an NMOS portion 106 of CMOS transistor structure 101 while channel material layers 115 are within a PMOS portion 107 of CMOS transistor structure 101.

In accordance with some embodiments, NMOS and PMOS channel material layers have complementary chemical compositions where one composition is advantageous for an N-type transistor and the other composition is advantageous for a P-type transistor. For example, channel material layers 115 may each be a first Group IV, Group III-V, metal oxide, or metal chalcogenide semiconductor material while channel material layers 116 are each a second Group IV, Group III-V, metal oxide, or metal chalcogenide semiconductor material. In some specific Group IV embodiments, channel material layers 115 comprise primarily silicon and may be substantially (pure) silicon while channel material layers 116 comprise germanium (e.g., Si₁₋ₓGe_{X}, Ge₁₋ₓSn_{X}, or substantially pure Ge).

In some alternative Group III-V embodiments, channel material layers 115 comprise a III-V material offering higher electron mobility, such as InGaAs, or InAs, for example. For such embodiments, channel material layers 116 may further comprise another III-V material offering higher hole mobility, or may comprise a Group IV material (e.g., substantially pure Ge) having higher hole mobility than the III-V composition of channel material layers 115. In other embodiments, channel material layers 115 comprise a transition metal and a chalcogen. The chalcogen may be sulfur, selenium, and tellurium (e.g., MSₓ, MSeₓ, or MTeₓ). The transition metal may be any transition metal such as any element of groups 4 through 11, the group 3 elements scandium and yttrium, and the inner transition metals (e.g., f-block lanthanide and actinide series). Advantageous transition metals for channel material layers 115 within NMOS portion 106 include molybdenum and tungsten while advantageous transition metals for channel material layers 116 within PMOS portion 107 include Cu and In. In still other embodiments, channel material layers 115 comprise one or more first metals and oxygen (i.e., first metal oxide semiconductor), such as, Indium, gallium zinc oxide (e.g., InGaZnOₓ or simply “IGZO”) while channel material layers 116 comprise one or more second metals and oxygen (i.e., a second metal oxide semiconductor), such as CuOₓ.

In accordance with some embodiments, NMOS and PMOS channel material layers of CMOS transistor structure 101 have complementary crystallinity where one crystal structure and/or crystal orientation is advantageous for NMOS portion 106 and the other crystal structure and/or crystal orientation is advantageous for PMOS portion 107. In some embodiments where channel material layers 115 and 116 are both crystalline (e.g., substantially monocrystalline), channel material layers 115 have cubic crystalline of a first crystallographic orientation advantageous for an N-type transistor while the crystallinity of channel material layers 116 is also cubic, but with second crystallographic orientation advantageous for a P-type transistor. For example, channel material layers 115 may have a (100) crystallographic orientation (i.e., <100> coincident with z-axis in FIG. 1) for maximum electron mobility within the (e.g., x-y) plane of channel material layers 115. In such embodiments, channel material layers 116 may instead have a (110) crystallographic orientation (i.e., <110> coincident with z-axis in FIG. 1) for maximum hole mobility within the (e.g., x-y) plane of channel material layers 116. In embodiments where crystallinity of channel material is complementary between NMOS and PMOS portions 106 and 107, the channel materials may be either of substantially the same chemical composition (e.g., both channel material layers 115 and 116 being substantially pure Si) or of different chemical compositions (e.g., channel material layers 115 may be pure Si while channel material layers 116 may be a SiGe alloy, Ge, or another composition). Hence, crystallinity may be the only significant variation between complementary channel materials, or may augment a difference in chemical composition between complementary channel materials.

As further illustrated in FIG. 1, NMOS portion 106 further comprises N-type source and drain 121 coupled to, and in contact with, channel material layers 115. N-type source and drain 121 may have any chemical composition and microstructure suitable for an NMOS transistor. N-type source and drain 121 may include monocrystalline or polycrystalline semiconductor material. In some embodiments, N-type source and drain 121 include a Group IV or III-V semiconductor material doped with any impurity dopants known to be suitable for the desired conductivity type, and to any concentration known to be suitable for transistors.

PMOS portion 107 further comprises P-type source and drain 122 coupled to, and in contact with, channel material layers 116. P-type source and drain 122 is in a vertical (e.g., along z-axis) stack with N-type source and drain 121. Space between N-type source and drain 121 and P-type source and drain 122 may be filled with any suitable insulator 154. Insulator 154 may be SiO₂ or a low-k dielectric material (e.g., SiOCH), for example. P-type source and drain 122 may have any chemical composition and microstructure suitable for a PMOS transistor. Source and drain 122 may include monocrystalline or polycrystalline semiconductor material. In some embodiments, source and drain 122 include a Group IV or III-V semiconductor material doped with any impurity dopants known to be suitable for the desired conductivity type, and to any concentration known to be suitable for transistors. In some exemplary embodiments, source and drain 121 predominantly silicon doped with any suitable concentration of donor impurities while source and drain 122 is predominantly silicon and/or germanium doped with any suitable concentration of acceptor impurities.

A gate stack 111 is between individual ones of channel material layers 115. Gate stack 111 may include one or more gate insulator materials and one or more gate electrode materials advantageous for NMOS portion 106. Another gate stack 112 is between individual ones of channel material layers 116. Gate stack 112 may include one or more gate insulator materials and one or more gate electrode materials advantageous for PMOS portion 107. In some embodiments, gate stack 111 includes a first high-k dielectric or ferroelectric material advantageous for N-type transistors and a first workfunction metal advantageous for N-type transistors while gate stack 112 includes a second high-k dielectric or ferroelectric material advantageous for P-type transistors and a second workfunction metal advantageous for P-type transistors.

Exemplary high-k dielectrics include metal oxides (e.g., comprising one or more of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate), or metal silicates (e.g., comprising one or more of above metals, oxygen and silicon). Examples of work function metals include ruthenium, palladium, platinum, cobalt, nickel, and conductive metal oxides (e.g., ruthenium oxide), hafnium, zirconium, titanium, tantalum, aluminum, alloys of these metals, and carbides of these metals such as hafnium carbide, zirconium carbide, titanium carbide, tantalum carbide, and aluminum carbide.

One or more spacer dielectrics 141 may be laterally adjacent to gate stacks 111, 112 and/or between channel material layers 115 and channel material layers 116. Spacer dielectrics 141 may have any suitable composition, such as, but not limited to, SiN, SiO, SiON, or a low-k dielectric material (e.g., SiOCH).

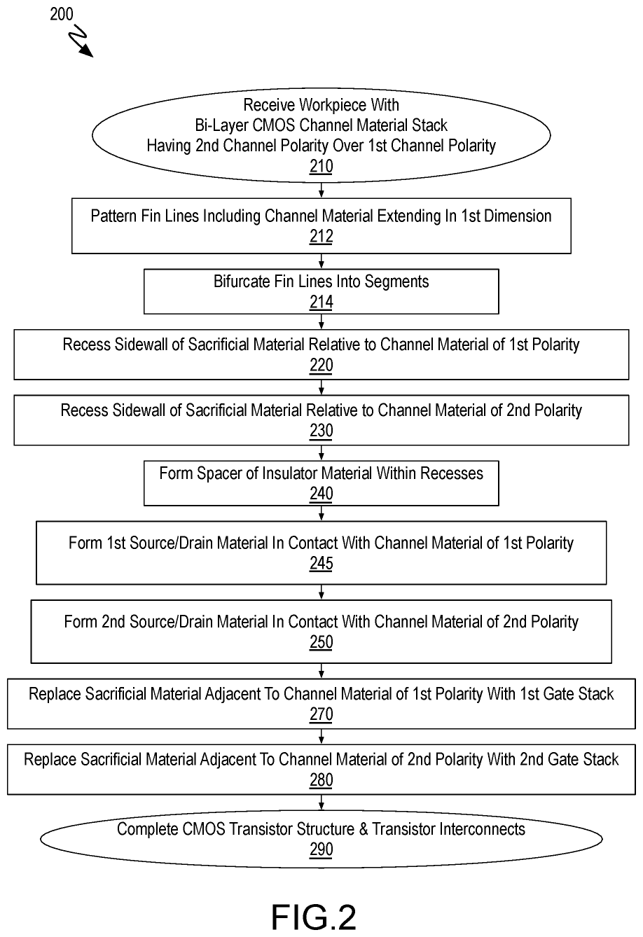

Stacked CMOS transistor structures 101-104 may be fabricated according to a variety of methods film processing techniques. FIG. 2 is a flow diagram illustrating methods 200 for forming a stacked CMOS transistor structure comprising complementary channel materials, in accordance with some embodiments.

Methods 200 begin at input 210 where a workpiece including a CMOS channel material stack is received. The CMOS channel material stack includes channel material advantageous for a first transistor polarity (e.g., P-type) over channel material advantageous for a second transistor polarity (e.g., N-type). In some embodiments, the channel material stack is a bi-layer stack comprising a plurality of bi-layers. Advantageously, throughout the CMOS channel material stack, each bi-layer comprises a first semiconductor material layer in contact with a second semiconductor material layer. As described further below, within an NMOS region of the channel material stack, the first semiconductor material is coupled to an N-type source and drain, and a first gate stack replaces the second semiconductor material. Within a PMOS region of the channel material stack, the second semiconductor material is coupled to a P-type source and drain, and a second gate stack replaces the first semiconductor material. Therefore, within complementary portions of a stacked CMOS transistor structure, the first and second semiconductor materials are either retained as complementary channel materials or removed as complementary sacrificial materials.

Methods 200 continue at block 212 the channel material stack is patterned into “fin” lines extending in a first dimension, for example according to any lithographic patterning process. For exemplary embodiments, fin lines may extend any length along a first dimension and have a width in a second, orthogonal dimension. Any lithographic masking process and material etch process(es) may be practiced at block 212. At block 214, the fin lines are bifurcated into fin segments with each fin segment defining a transistor channel material stack. This bifurcation may be with a second lithographic patterning process defining lines/trenches that are substantially orthogonal to the fin lines, for example.

At block 220, within each transistor channel material stack, an exposed sidewall of a first sacrificial material layer is recess etched selectively relative to channel material of a first transistor polarity (e.g., P-type or N-type). At block 230, within each transistor channel material stack, an exposed sidewall of a second sacrificial material layer is recess etched selectively relative to channel material of a second transistor polarity (e.g., N-type or P-type).

At block 240, a spacer of insulator (e.g., dielectric) material is formed within the recesses formed at blocks 220 and 230. At block 245, a first source and drain is formed in contact with channel material of a first transistor polarity. At block 250, a second source and drain is formed in contact with channel material of a second transistor polarity. The first source and drain and the second source and drain may be formed with epitaxial growth processes, for example seeding from sidewall surfaces of adjacent channel material layers. An insulator, such as SiO, SiN, SiON, or SiOCH, may be deposited after a first epi growth performed at block 245 and prior to a second epi growth performed at block 250 so that the second source and drain is electrically insulated from the first source and drain.

Methods 200 continue at block 270 where sacrificial material adjacent to channel material of a first polarity is replaced with a first gate stack. As described further below, for embodiments where removal of the sacrificial material may be detrimental to the channel material of a second polarity (e.g., where the sacrificial material has the same chemical composition as that of the channel material of second polarity), a first portion of a CMOS channel material stack may be protected during an etch of the sacrificial material. Following removal of sacrificial material, a first gate insulator may be deposited on exposed surfaces of channel material of the first polarity. Any suitable deposition process, such as an atomic layer deposition (ALD) process may be practiced, for example to form a high-k gate insulator. A first workfunction metal may then be deposited upon the gate insulator to complete the first gate stack.

At block 280, sacrificial material adjacent to channel material of a second polarity is replaced with a second gate stack. As described further below, for embodiments where removal of the sacrificial material may be detrimental to the channel material of the first polarity (e.g., where the sacrificial material has the same chemical composition as that of the channel material of first polarity), a second portion of a CMOS channel material stack may be protected during an etch of the sacrificial material. Following removal of sacrificial material, a second gate insulator may be deposited on exposed surfaces of channel material of the second polarity. Any suitable deposition process, such an ALD process may again be practiced, for example to form a high-k gate insulator. A second workfunction metal may then be deposited upon the gate insulator to complete the second gate stack.

Methods 200 end at output 290 where a stacked CMOS transistor structure is completed and levels of metallization are fabricated over the stacked CMOS transistor structure to interconnect gate, source and drain terminals of the stacked CMOS transistor structure with terminals of other transistors and/or circuit nodes. Any known techniques may be practiced at output 290.

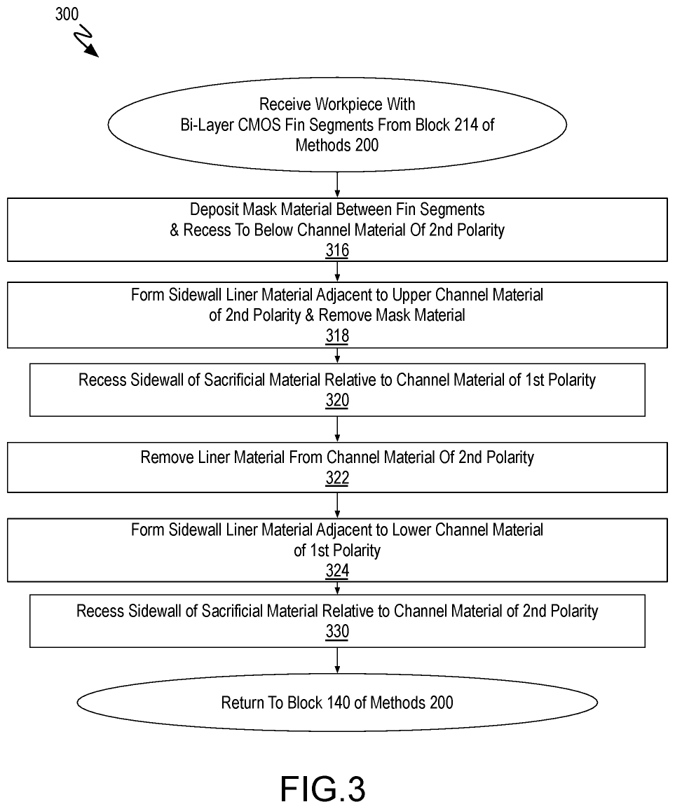

FIG. 3 is a flow diagram illustrating methods 300 for forming complementary channel materials of a stacked CMOS transistor structure, in accordance with some exemplary embodiments. Methods 300 may, for example, be practiced as a portion of methods 200. In advantageous embodiments, a workpiece with bi-layer CMOS fin segments generated at block 214 of methods 200 is received as an input to methods 300. According to methods 300 upper and lower portions of a bi-layer semiconductor material stack are separately processed such that a first semiconductor material can be retained as channel material layers within a lower portion of the stack and recessed as sacrificial material layers within an upper portion of the stack while a second semiconductor material can be retained as channel material layers within the upper portion of the stack and recessed as sacrificial material layers within the lower portion of the stack. Methods 300 therefore enable a stack of channel material layers having different composition and/or crystalline orientation to be separately prepared into complementary portions of a stacked CMOS transistor.

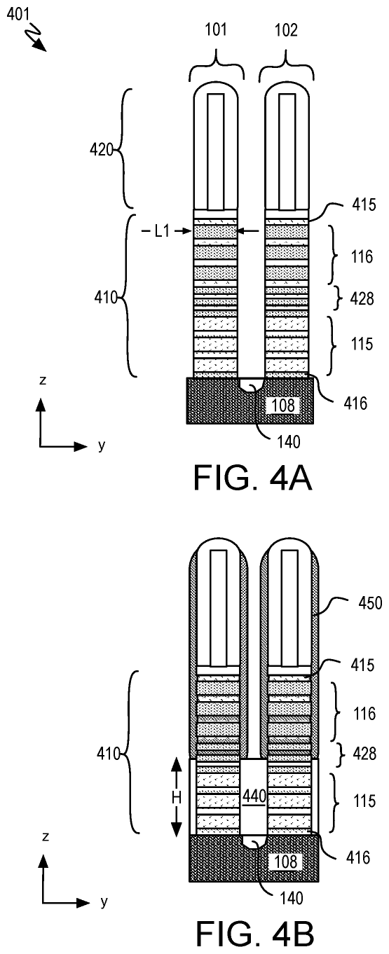

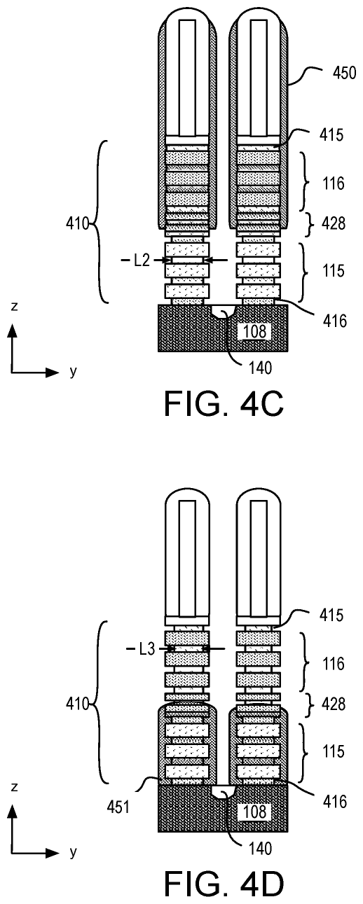

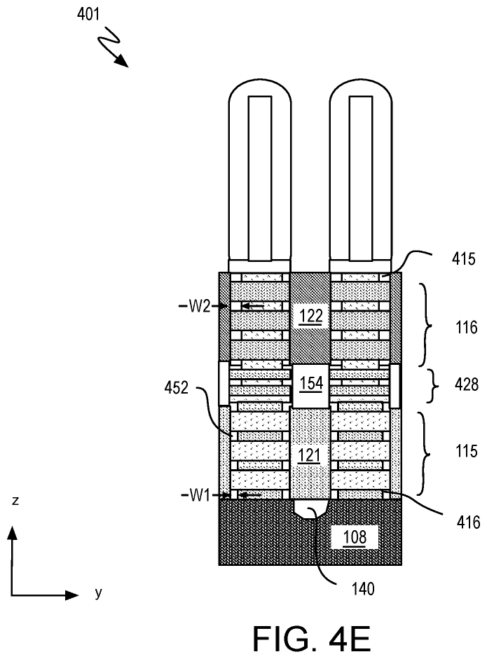

FIG. 4A-4E_illustrate cross-sectional views through the y-z plane of a structure 401 evolving to include complementary channel materials coupled to complementary source and drain materials, in accordance with some embodiments of the methods 300. The y-z plane illustrated corresponds to the y-z plane illustrated in FIG. 1.

In the example shown in FIG. 4A, structure 401 includes a pair of bi-layer CMOS fin segments 410 over substrate material 108. In this example a first of bi-layer fin segments 410 is a precursor structure to stacked CMOS transistor structure 101 and a second of bi-layer fin segments 410 is a precursor structure to stacked CMOS transistor structure 102. A fin segment mask 420 employed to define a channel material length L1 is over each bi-layer fin segment 410. Within a lower portion of each bi-layer fin segment 410 there is a plurality of channel material layers 115 interleaved with sacrificial material 416. Within an upper portion of each bi-layer fin segment 410 there is a plurality of channel material layers 116 interleaved with sacrificial material 415. Channel material layers 115 and 116 may have any of the compositions described above. In some advantageous embodiments, sacrificial material 415 has substantially the same composition as channel material layer 115, and sacrificial material 416 has substantially the same composition as channel material layer 116. Accordingly, it may be advantageous to independently process upper and lower portions of each bi-layer fin segment 410.

Channel material layers 115 and 116 may also have any of the crystal orientations described above. For embodiments where channel material layers 115 (and sacrificial material 416) have a first orientation (e.g., (100)) and channel material layers 116 (and sacrificial material 415) have a second orientation (e.g., (110)), upper and lower portions of each bi-layer fin segment 410 may be processed independently. Such independent processing may again be advantageous, for example if a recess etch process is dependent on crystallography.

Between the upper and lower portions of each bi-layer fin segment 410 there is a buffer 428. Buffer 428 may comprise one or more material layers that may ultimately be retained within, or removed from, CMOS transistor structures 101, 102. Buffer 428 provides vertical (e.g., z-axis) separation between complementary channel material layers 115 and 116. Buffer 428 may also function as a compositional and/or crystallographic transition region, for example where a bi-layer material stack is epitaxially grown. In alternative embodiments, buffer 428 may function as a bonding region, for example where two epitaxially grown bi-layer material stacks, one comprising channel material layers 115 and another comprising channel material layers 116, are joined together within any suitable bonding process.

In the illustrated embodiment, buffer 428 comprises a bi-layer superlattice including layers of the same composition and crystal orientation as channel material layers 115 and 116. In other embodiments, buffer 428 includes one or more compositionally distinct material layers. In some examples where channel material layers 116 have a different crystal orientation than channel material layers 115, buffer 428 includes a distinct material, such as graphene, that may be suitable for changing lattice orientations in-situ, particularly between two cubic crystals of a similar lattice constant. For embodiments where a CMOS channel material stack is formed through bonding, buffer 428 may comprise one or more dielectric material layers, such as SiO, SiN, SiON, etc.

Returning to FIG. 3, methods 300 continue at block 316, where a mask material is deposited between (and over) the bi-layer fin segments. The mask material may be any suitable material, such as diamond-like carbon (DLC) or another CVD carbon material, for example. Following deposition, a top surface of the mask material may be planarized and then recessed with an etch process to a height below the channel material layers within the upper portion of the bi-layer fin segments. With the lower portion of the bi-layer fin segments protected by the mask material, at block 318 a sidewall liner material may be deposited upon a sidewall of channel material layers within the upper portion of the bi-layer fin segments. The liner material may be any suitable dielectric material, for example, and deposited with any sufficiently conformal deposition technique (e.g., ALD). While the upper portion of the bi-layer fin segments are protected by the liner material, the mask material can be removed from the lower portion of the bi-layer fin segments.

At block 320, sacrificial material within the lower portion of a bi-layer fin segment is etched to recess sidewall(s) of the sacrificial material selectively over channel material of a first polarity. For example, SiGe may be recess etched from between channel material layers of Si. FIG. 4B further illustrates some embodiments where a mask material 440 (e.g., DLC) has been deposited, planarized and recess etched to height H that leaves sidewalls of channel material layers 116 exposed until liner 450 is deposited. FIG. 4C further illustrates removal of mask material 440, and a subsequent controlled etch of sacrificial material 416. The etch process recesses opposite sidewalls of sacrificial material 416, symmetrically reducing them to length L2 while channel material layers 116 are protected by liner 450.

Methods 300 (FIG. 3) continue at block 322 where liner material is removed from the upper portion of the material stack. At block 324, additional liner material may then be formed adjacent to the lower channel material of a first polarity. While the lower portion of the material stack is protected by the liner material at block 330, sacrificial material within the upper portion of a bi-layer fin segment is etched to recess sidewall(s) of the sacrificial material selectively over channel material of a second polarity. For example, silicon may be recessed etched from between channel material layers of SiGe. FIG. 4D further illustrates removal of liner 450, formation of liner 451, and a subsequent controlled etch of sacrificial material 415. The etch process recesses opposite sidewalls of sacrificial material 415, symmetrically reducing them to a length L3 while channel material layers 115 are protected by liner 451. Notably, because of the independent etching of sacrificial material layers 415 and 416, the lengths L2 and L3 can be controlled to be substantially equal, but may also be controlled to be different. Length L2 may be longer or shorter than length L3, for example to balance, or otherwise modulate source/drain off-state leakage for channel material layers of a first polarity relative to that for channel material layers of a second polarity.

Returning to FIG. 3, methods 300 end by returning to block 140 of methods 200 (FIG. 2) where a spacer of insulator material is formed within the recesses formed by methods 300. Complementary source and drain material may then formed according to methods 200 to arrive at structure 401, substantially as illustrated in FIG. 4E. As shown, all liner material has been removed. A p-type source and drain 121 and an n-type source and drain 122 has been formed in contact with sidewalls of channel material layers 115 and 116, respectively. Spacer insulator 141 is within the recesses formed between sacrificial material layers 416, 415 and the adjacent sources and drains 121, 122. Lateral widths W1 and W2 of spacer insulator 141 may vary as a function of the lengths L2, L3 of sacrificial material layers 415, 416. Generally, spacer widths W1, W2 are equal to a difference between the adjacent channel material length L1 and sacrificial material lengths L2, L3, respectively.

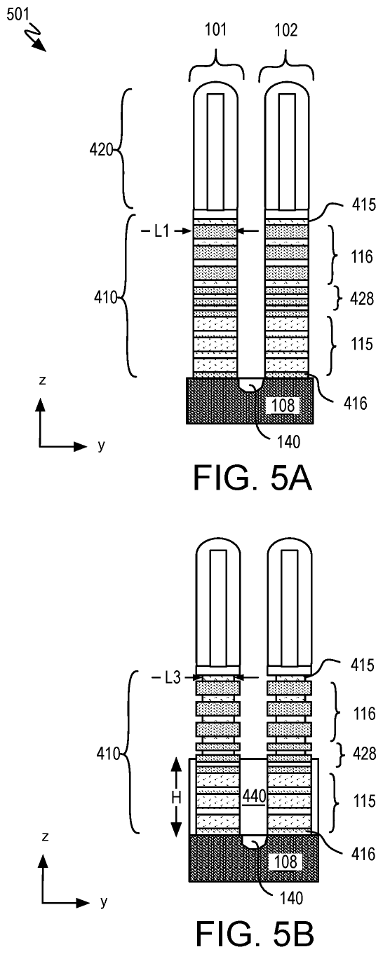

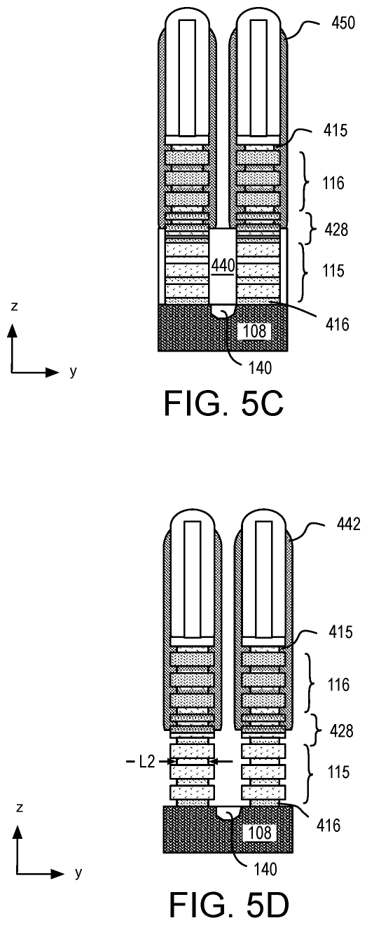

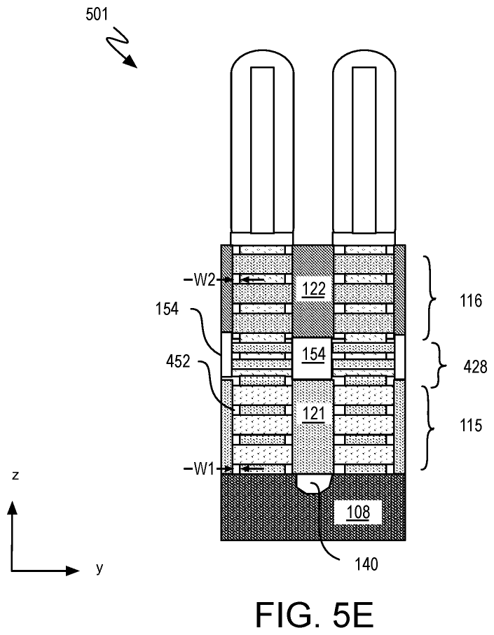

Notably, the exemplary techniques of depositing, planarizing and recess etching a mask material in combination with forming a substantially conformal dielectric liner, may be practiced in different sequences to independently process top and bottom portions of bi-layer fin segments. While methods 300 illustrate a bottom-up approach to fabricating complementary source materials coupled to complementary channel materials separated by complementary sacrificial materials, the blocks of methods 300 may be alternatively sequenced, for example to implement top-down processing of sacrificial material layers as further illustrated in FIG. 5A-5E.

In FIG. 5A, structure 501 includes a pair of bi-layer CMOS fin segments 410 over substrate material 108 substantially as described above for structure 401. Bi-layer fin segments 410 are again precursor structures to stacked CMOS transistor structures 101, 102. FIG. 5B further illustrates deposition and etch back of mask material 440 to height H. Sacrificial material layers 415 are then recess etched to reach length L3 within the upper portion of bi-layer fin segments 410. FIG. 5C illustrates a subsequent deposition of liner 450 adjacent to sidewalls of sacrificial material 415 and channel material layers 116. Mask material 440 may then be removed, as further illustrated in FIG. 5D, and sacrificial material layers 416 recess etched to reach length L2 within the lower portion of bi-layer fin segments 410. FIG. 5E further illustrates the formation of source and drain materials 121, 122, rendering structure 501 substantially identical to structure 401.

Methods 300, and variants thereof, exemplified by FIGS. 4A-4E and 5A-5E may be optionally adapted to independently replace sacrificial materials from upper and lower portions of a material stack with complementary gate structures. The complementary processing of methods 300 performed to facilitate the formation of complementary source and drain materials may also be performed to further facilitate the formation of complementary gate insulator and/or gate electrode materials, for example at blocks 270 and 280 of methods 200 (FIG. 2).

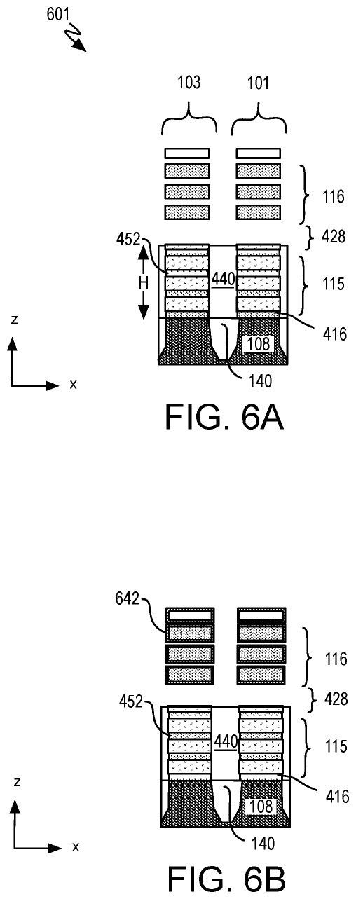

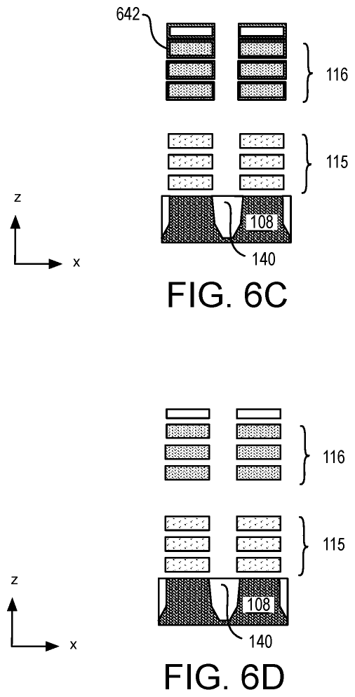

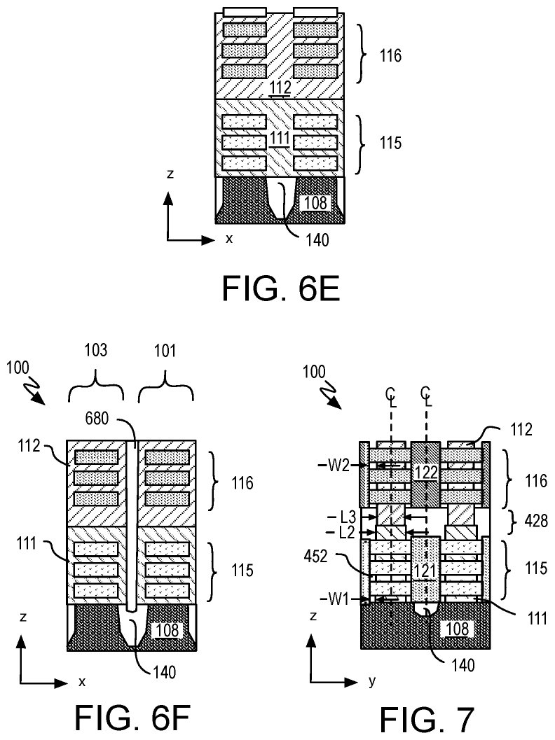

FIG. 6A-6F illustrate cross-sectional views through an x-z plane of a stacked material structure 601 evolving from stacked material structure 401 (FIG. 4E) or 501 (FIG. 5E) into the stacked CMOS transistor structures 101 and 103 substantially as illustrated in FIG. 1. As shown in FIG. 1, the plane illustrated in FIG. 6A-6F is substantially orthogonal to the plane illustrated in FIG. 4A-4E or FIG. 5A-5E. Referring first to FIG. 6A, mask material 440 is deposited and etched back to height H. Sacrificial material layers between channel material layers 116 are then substantially removed, for example with a selective etch process, exposing surfaces of nanowires/ribbons comprising channel material of a first polarity (e.g., p-type). One or more material layers of buffer 428 may also be substantially removed.

In FIG. 6B, a liner 642 is formed over channel material layers 116. Liner 642 may be sacrificial or a permanent feature of a first gate stack (e.g., a first gate insulator and first work function metal). With channel material layers 116 protected, sacrificial material layers between channel material layers 115 are then substantially removed, for example with another selective etch process, exposing surfaces of nanowires/ribbons comprising channel material of a second polarity (e.g., n-type). A second gate insulator and a second work function metal may then be formed around the exposed nanowires/ribbons to arrive at a stacked CMOS transistor structure as illustrated in FIG. 6E, and substantial as introduced in FIG. 1. Once formed, gate stacks 111, 112 may be bifurcated between transistor structures 103, 101, for example with a gate-cut isolation dielectric 680, as illustrated in FIG. 6F.

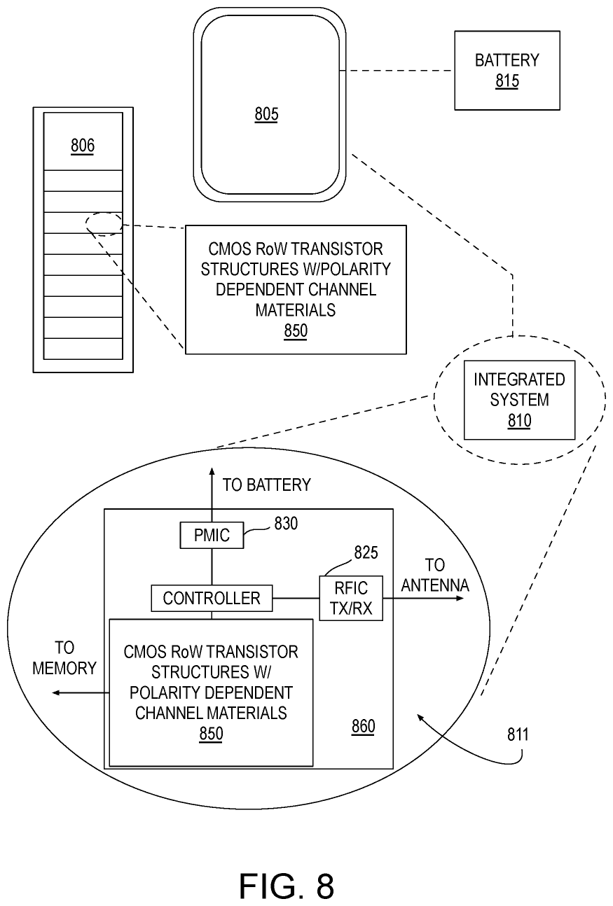

FIG. 7 illustrates a cross-sectional view through the y-z plane of the stacked CMOS transistor structure 100 illustrated in FIG. 6F, in accordance with some embodiments. As shown, in FIG. 7, gate stack 111 is associated with a gate length L2 that is a function of the amount of a first sacrificial material recess etch as described elsewhere herein. Gate stack 112 is similarly associated with another gate length L3 that is a function of the amount of a second, independent, sacrificial material recess etch, as described herein. For embodiments where buffer 428 is sacrificial, gate stack 111 is in contact with gate stack 112 within a region between n-type source and drain 121 and p-type source and drain 122. As further shown in FIG. 7, a sum of the length L2 and width W1 of insulator 141 is substantially equal to a sum of length L2 and width W2 of insulator 141.

The transistor structures described above may be employed in a wide range of IC devices and further integrated in a wide range of computer-based applications. FIG. 8 illustrates a mobile computing platform 805 and a server machine 806 employing a packaged IC die including a stacked CMOS transistor structures 850 with polarity dependent channel materials, for example as described elsewhere herein. Server machine 806 may be any commercial server, for example including any number of high-performance computing platforms disposed within a rack and networked together for electronic data processing, which in the exemplary embodiment includes a packaged IC die comprising stacked CMOS transistor structure 850, for example as described elsewhere herein.

The mobile computing platform 805 may be any portable device configured for each of electronic data display, electronic data processing, wireless electronic data transmission, or the like. For example, the mobile computing platform 805 may be any of a tablet, a smart phone, laptop computer, etc., and may include a display screen (e.g., a capacitive, inductive, resistive, or optical touchscreen), an integrated system 810, and a battery 815.

As illustrated in the expanded view, one or more of a power management integrated circuit (PMIC) 830 or RF (wireless) integrated circuit (RFIC) 825 including a wideband RF (wireless) transmitter and/or receiver may be further coupled to an IC die comprising stacked CMOS transistor structure 850. A PMIC may perform battery power regulation, DC-to-DC conversion, etc., and so has an input coupled to battery 815 and an output providing a current supply to other functional modules. An RFIC may have an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G and beyond.

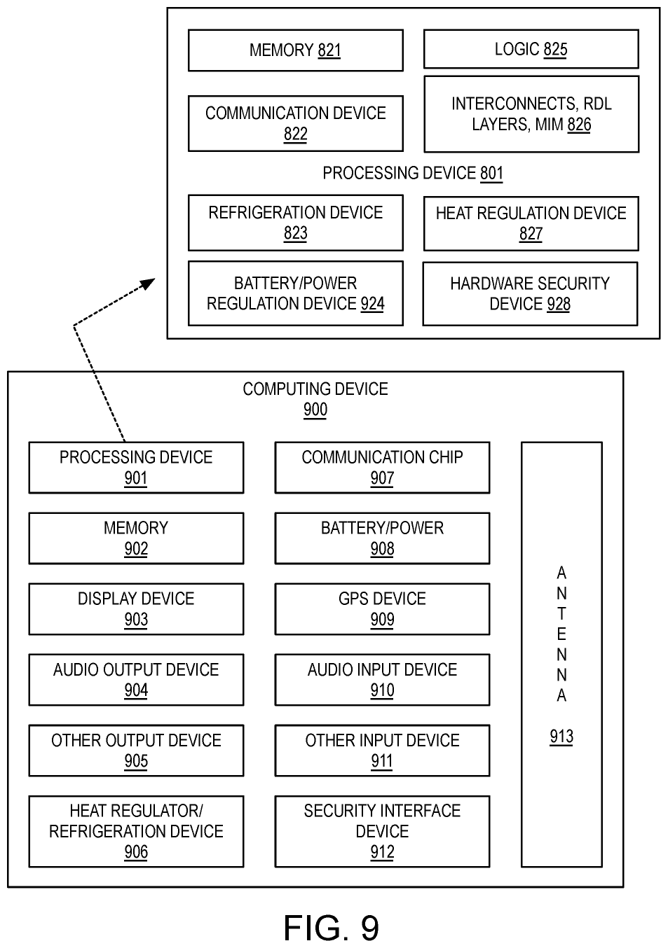

FIG. 9 is a block diagram of a cryogenically cooled computing device 900 in accordance with some embodiments. For example, one or more components of computing device 900 may include any of the stacked CMOS transistor structures discussed elsewhere herein. A number of components are illustrated in FIG. 9 as included in computing device 900, but any one or more of these components may be omitted or duplicated, as suitable for the application. In some embodiments, some or all of the components included in computing device 900 may be attached to one or more printed circuit boards (e.g., a motherboard). In some embodiments, various ones of these components may be fabricated onto a single system-on-a-chip (SoC) die. Additionally, in various embodiments, computing device 900 may not include one or more of the components illustrated in FIG. 9, but computing device 900 may include interface circuitry for coupling to the one or more components. For example, computing device 900 may not include a display device 903, but may include display device interface circuitry (e.g., a connector and driver circuitry) to which display device 903 may be coupled.

Computing device 900 may include a processing device 901 (e.g., one or more processing devices). As used herein, the term processing device or processor indicates a device that processes electronic data from registers and/or memory to transform that electronic data into other electronic data that may be stored in registers and/or memory. Processing device 901 may include a memory 921, a communication device 922, a refrigeration/active cooling device 923, a battery/power regulation device 924, logic 925, interconnects 926 (i.e., optionally including redistribution layers (RDL) or metal-insulator-metal (MIM) devices), a heat regulation device 927, and a hardware security device 928.

Processing device 901 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 901 may include a memory 902, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 921 includes memory that shares a die with processing device 901. This memory may be used as cache memory and may include embedded dynamic random-access memory (eDRAM) or spin transfer torque magnetic random-access memory (STT-M RAM).

Computing device 900 may include a heat regulation/refrigeration device 906. Heat regulation/refrigeration device 906 may maintain processing device 901 (and/or other components of computing device 900) at a predetermined low temperature during operation. This predetermined low temperature may be any temperature discussed elsewhere herein.

In some embodiments, computing device 900 may include a communication chip 907 (e.g., one or more communication chips). For example, the communication chip 907 may be configured for managing wireless communications for the transfer of data to and from computing device 900. The term “wireless” and its derivatives may be used to describe circuits, devices, systems, methods, techniques, communications channels, etc., that may communicate data through the use of modulated electromagnetic radiation through a nonsolid medium.

Communication chip 907 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 907 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 907 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 907 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 907 may operate in accordance with other wireless protocols in other embodiments. Computing device 900 may include an antenna 913 to facilitate wireless communications and/or to receive other wireless communications (such as AM or FM radio transmissions).

In some embodiments, communication chip 907 may manage wired communications, such as electrical, optical, or any other suitable communication protocols (e.g., the Ethernet). As noted above, communication chip 907 may include multiple communication chips. For instance, a first communication chip 907 may be dedicated to shorter-range wireless communications such as Wi-Fi or Bluetooth, and a second communication chip 907 may be dedicated to longer-range wireless communications such as GPS, EDGE, GPRS, CDMA, WiMAX, LTE, EV-DO, or others. In some embodiments, a first communication chip 907 may be dedicated to wireless communications, and a second communication chip 907 may be dedicated to wired communications.

Computing device 900 may include battery/power circuitry 908. Battery/power circuitry 908 may include one or more energy storage devices (e.g., batteries or capacitors) and/or circuitry for coupling components of computing device 900 to an energy source separate from computing device 900 (e.g., AC line power).

Computing device 900 may include a display device 903 (or corresponding interface circuitry, as discussed above). Display device 903 may include any visual indicators, such as a heads-up display, a computer monitor, a projector, a touchscreen display, a liquid crystal display (LCD), a light-emitting diode display, or a flat panel display, for example.

Computing device 900 may include an audio output device 904 (or corresponding interface circuitry, as discussed above). Audio output device 904 may include any device that generates an audible indicator, such as speakers, headsets, or earbuds, for example.

Computing device 900 may include an audio input device 910 (or corresponding interface circuitry, as discussed above). Audio input device 910 may include any device that generates a signal representative of a sound, such as microphones, microphone arrays, or digital instruments (e.g., instruments having a musical instrument digital interface (MIDI) output).

Computing device 900 may include a global positioning system (GPS) device 909 (or corresponding interface circuitry, as discussed above). GPS device 909 may be in communication with a satellite-based system and may receive a location of computing device 900, as known in the art.

Computing device 900 may include another output device 905 (or corresponding interface circuitry, as discussed above). Examples include an audio codec, a video codec, a printer, a wired or wireless transmitter for providing information to other devices, or an additional storage device.

Computing device 900 may include another input device 911 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 900 may include a security interface device 912. Security interface device 912 may include any device that provides security measures for computing device 900 such as intrusion detection, biometric validation, security encode or decode, managing access lists, malware detection, or spyware detection. In some examples, security interface device 912 comprises OTP ROM further including a via MIM fuse, for example as described elsewhere herein.

Computing device 900, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the disclosure is not limited to the embodiments so described, but instead can be practiced with modification and alteration without departing from the scope of the appended claims. For example, the above embodiments may include specific combinations of features as further provided below.

In first examples an apparatus comprises a first stack of first channel material layers coupled to an n-type source and drain. The first channel material layers comprise substantially pure Si of a first crystal orientation. The apparatus comprises a second stack of second channel material layers in a vertical stack with the first stack of first channel material layers and coupled to a p-type source and drain. The p-type source and drain are in a vertical stack with the n-type source and drain with an insulator therebetween. The second channel material layers comprise other than substantially pure silicon or have a second crystal orientation, different than the first crystal orientation. The apparatus comprises a first gate stack comprising a first gate insulator and a first gate electrode material between individual ones of the first channel material layers. The apparatus comprises a second gate stack comprising a second gate insulator and a second gate electrode material between individual ones of the second channel material layers.

In second examples, for any of the first examples the second channel material layers comprise Ge.

In third examples, for any of the first through second examples the first crystal orientation is (100) relative to a reference plane through the vertical stack and the second crystal orientation is (110) relative to the reference plane.

In fourth examples, for any of the first through third examples the second channel material layers comprise other than substantially pure silicon, the first crystal orientation is (100) relative to a reference plane through the vertical stack, and the second crystal orientation is (110) relative to the reference plane.

In fifth examples, for any of the first through fourth examples the first gate electrode has a first length between the n-type source and drain and substantially centered with a second length of the second gate electrode between the p-type source and drain.

In sixth examples, for any of the fifth examples the first length of the first gate electrode is different than the second length of the second gate electrode.

In seventh examples, for any of the sixth examples an insulator occupies a lateral space of a first width between the n-type source and drain and the first gate electrode, and wherein the insulator occupies a lateral space of a second width between the p-type source and drain and the second gate electrode.

In eighth examples, for any of the seventh examples a sum of the first length of the first gate electrode and the first width of the insulator is substantially equal to a sum of the second length of the second gate electrode and the second width of the insulator.

In ninth examples, for any of the fifth through eighth examples a portion the first gate stack is in contact with the second gate stack within a region between the n-type source and drain and the p-type source and drain.

In tenth examples, an integrated circuit (IC) device comprises a stacked CMOS transistor structure comprising a first stack of first channel material layers coupled to an n-type source and drain, the first channel material layers comprising a first group IV semiconductor of a first crystal orientation. The CMOS transistor structure comprises a second stack of second channel material layers in a vertical stack with the first stack of first channel material layers and coupled to a p-type source and drain. The p-type source and drain are in a vertical stack with the n-type source and drain with an insulator therebetween. The second channel material layers comprise a second group IV semiconductor or have a second crystal orientation. The second group IV semiconductor or second crystal orientation has higher hole mobility than the first group IV semiconductor of the first crystal orientation. The CMOS transistor structure comprises one or more gate stacks, each comprising a gate insulator and a gate electrode material, between individual ones of the first and second channel material layers. The IC device comprises interconnect metallization levels over the stacked CMOS transistor structure. The interconnect metallization levels interconnect the stacked CMOS transistor structure with other stacked CMOS transistor structures.

In eleventh examples, for any of the eleventh examples the first Group IV semiconductor is substantially pure Si and the second channel material layers comprise an alloy of Si and Ge.

In twelfth examples, for any of the tenth through eleventh examples the first channel material layers have a (100) crystal orientation and the second channel material layers have a (110) crystal orientation.

In thirteenth examples a method comprises forming a fin comprising a plurality of bi-layers. Each bi-layer comprises a first Group IV semiconductor material layer in contact with a second Group IV semiconductor material layer. The method comprises recessing a sidewall of the first Group IV semiconductor material layer within first ones of the bi-layers proximal to a bottom of the fin. The method comprises recessing a sidewall of the second Group IV semiconductor material layer within second ones of the bi-layers proximal to a top of the fin. The method comprises forming a first source and drain material coupled to the second Group IV semiconductor material layer within the first ones of the bi-layers. The method comprises forming a second source and drain material coupled to the second Group IV semiconductor material layer within the second ones of the bi-layers. The method comprises replacing, with a first gate stack, the first Group IV semiconductor material layer within the first ones of the bi-layers. The method comprises replacing, with a second gate stack, the second Group IV semiconductor material layer within the second ones of the bi-layers.

In fourteenth examples, for any of the thirteenth examples the method further comprises forming a material adjacent to the second ones of the bi-layers prior to recessing the sidewall of the first Group IV semiconductor material layer within the first ones of the bi-layers, and forming a material adjacent to the first ones of the bi-layers prior to recessing the sidewall of the second Group IV semiconductor material layer within the second ones of the bi-layers.

In fifteenth examples, for any of the thirteenth through fourteenth examples forming the material adjacent to the first ones of the bi-layers comprises depositing diamond-like carbon (DLC) around the fin and recess etching a top surface of the DLC to a height below the second ones of the bi-layers.

In sixteenth examples for any of the thirteenth through fifteenth examples forming the material adjacent to the second ones of the bi-layers comprises conformally depositing a dielectric material around the fin.

In seventeenth examples for any of the thirteenth through sixteenth examples the method comprises forming a material adjacent to the second ones of the bi-layers prior to replacing, with the first gate stack, the first Group IV semiconductor material layer within the first ones of the bi-layers. The method comprises forming a material adjacent to the first ones of the bi-layers prior to replacing, with the second gate stack, the second Group IV semiconductor material layer within the second ones of the bi-layers.

In eighteenth examples, for any of the seventeenth examples forming the material adjacent to the first ones of the bi-layers comprises depositing diamond-like carbon (DLC) around the fin and recess etching a top surface of the DLC to a height below the second ones of the bi-layers.

In nineteenth examples, for any of the seventeenth examples forming the material adjacent to the second ones of the bi-layers comprises conformally depositing a dielectric material.

In twentieth examples, for any of thirteenth through nineteenth examples the first Group IV semiconductor material layer is substantially pure silicon and the second Group IV semiconductor material layer comprises Ge.

However, the above embodiments are not limited in this regard, and, in various implementations, the above embodiments may include the undertaking of only a subset of such features, undertaking a different order of such features, undertaking a different combination of such features, and/or undertaking additional features than those features explicitly listed. The scope of the disclosure should, therefore, be determined with reference to the appended claims, along with the full scope of equivalents to which such claims are entitled.

What is claimed is:

1. An apparatus, comprising:
a first stack of first channel material layers coupled to an n-type source and drain, the first channel material layers comprising substantially pure Si of a first crystal orientation;
a second stack of second channel material layers in a vertical stack with the first stack of first channel material layers and coupled to a p-type source and drain, wherein the p-type source and drain are in a vertical stack with the n-type source and drain with an insulator therebetween, and wherein the second channel material layers comprise other than substantially pure silicon or have a second crystal orientation, different than the first crystal orientation; and
a first gate stack comprising a first gate insulator and a first gate electrode material between individual ones of the first channel material layers; and
a second gate stack comprising a second gate insulator and a second gate electrode material between individual ones of the second channel material layers.

2. The apparatus of claim 1, wherein the second channel material layers comprise Ge.

3. The apparatus of claim 1, wherein the first crystal orientation is (100) relative to a reference plane through the vertical stack and the second crystal orientation is (110) relative to the reference plane.

4. The apparatus of claim 1, wherein:
the second channel material layers comprise other than substantially pure silicon;
the first crystal orientation is (100) relative to a reference plane through the vertical stack; and
the second crystal orientation is (110) relative to the reference plane.

5. The apparatus of claim 1, wherein the first gate electrode has a first length between the n-type source and drain and substantially centered with a second length of the second gate electrode between the p-type source and drain.

6. The apparatus of claim 5, wherein the first length of the first gate electrode is different than the second length of the second gate electrode.

7. The apparatus of claim 6, wherein an insulator occupies a lateral space of a first width between the n-type source and drain and the first gate electrode, and wherein the insulator occupies a lateral space of a second width between the p-type source and drain and the second gate electrode.

8. The apparatus of claim 7, wherein a sum of the first length of the first gate electrode and the first width of the insulator is substantially equal to a sum of the second length of the second gate electrode and the second width of the insulator.

9. The apparatus of claim 5, wherein a portion the first gate stack is in contact with the second gate stack within a region between the n-type source and drain and the p-type source and drain.

10. An integrated circuit (IC) device, comprising:
a stacked CMOS transistor structure comprising:
a first stack of first channel material layers coupled to an n-type source and drain, the first channel material layers comprising a first group IV semiconductor of a first crystal orientation;
a second stack of second channel material layers in a vertical stack with the first stack of first channel material layers and coupled to a p-type source and drain, wherein:
the p-type source and drain are in a vertical stack with the n-type source and drain with an insulator there between;
the second channel material layers comprise a second group IV semiconductor or have a second crystal orientation; and
the second group IV semiconductor or second crystal orientation has higher hole mobility than the first group IV semiconductor of the first crystal orientation; and
one or more gate stacks, each comprising a gate insulator and a gate electrode material, between individual ones of the first and second channel material layers; and
interconnect metallization levels over the stacked CMOS transistor structure, the interconnect metallization levels interconnecting the stacked CMOS transistor structure with other stacked CMOS transistor structures.

11. The IC device of claim 10, wherein the first Group IV semiconductor is substantially pure Si and the second channel material layers comprise an alloy of Si and Ge.

12. The IC device of claim 10, wherein the first channel material layers have a (100) crystal orientation and the second channel material layers have a (110) crystal orientation.

13. A method, comprising:
forming a fin comprising a plurality of bi-layers, wherein each bi-layer comprises a first Group IV semiconductor material layer in contact with a second Group IV semiconductor material layer;
recessing a sidewall of the first Group IV semiconductor material layer within first ones of the bi-layers proximal to a bottom of the fin;
recessing a sidewall of the second Group IV semiconductor material layer within second ones of the bi-layers proximal to a top of the fin;
forming a first source and drain material coupled to the second Group IV semiconductor material layer within the first ones of the bi-layers;
forming a second source and drain material coupled to the second Group IV semiconductor material layer within the second ones of the bi-layers;
replacing, with a first gate stack, the first Group IV semiconductor material layer within the first ones of the bi-layers; and
replacing, with a second gate stack, the second Group IV semiconductor material layer within the second ones of the bi-layers.

14. The method of claim 13, further comprising:
forming a material adjacent to the second ones of the bi-layers prior to recessing the sidewall of the first Group IV semiconductor material layer within the first ones of the bi-layers; and
forming a material adjacent to the first ones of the bi-layers prior to recessing the sidewall of the second Group IV semiconductor material layer within the second ones of the bi-layers.

15. The method of claim 14, wherein forming the material adjacent to the first ones of the bi-layers comprises depositing diamond-like carbon (DLC) around the fin and recess etching a top surface of the DLC to a height below the second ones of the bi-layers.

16. The method of claim 15, wherein forming the material adjacent to the second ones of the bi-layers comprises conformally depositing a dielectric material around the fin.

17. The method of claim 14, further comprising:
forming a material adjacent to the second ones of the bi-layers prior to replacing, with the first gate stack, the first Group IV semiconductor material layer within the first ones of the bi-layers; and
forming a material adjacent to the first ones of the bi-layers prior to replacing, with the second gate stack, the second Group IV semiconductor material layer within the second ones of the bi-layers.

18. The method of claim 17, wherein forming the material adjacent to the first ones of the bi-layers comprises depositing diamond-like carbon (DLC) around the fin and recess etching a top surface of the DLC to a height below the second ones of the bi-layers.

19. The method of claim 17, wherein forming the material adjacent to the second ones of the bi-layers comprises conformally depositing a dielectric material.

20. The method of claim 13, wherein the first Group IV semiconductor material layer is substantially pure silicon and the second Group IV semiconductor material layer comprises Ge.
